(19) United States
(12) Patent Application Publication
(10) Pub. No.: US 2026/0261263 A1
(43) Pub. Date: Sep. 3, 2026

(54) BINARY INVERTER CIRCUITS WITH CONFIGURABLE THRESHOLD VOLTAGES

(71) Applicants: Angel C. Abusleme Hoffman, Round Rock, TX (US); Agustin R. Campeny, Austin, TX (US); John L. Melanson, Austin, TX (US)

(72) Inventors: Angel C. Abusleme Hoffman, Round Rock, TX (US); Agustin R. Campeny, Austin, TX (US); John L. Melanson, Austin, TX (US)

(21) Appl. No.: 19/658,646

(22) Filed: Apr. 26, 2026

Related U.S. Application Data
(62) Division of application No. 18/440,796, filed on Feb. 13, 2024, now Pat. No. 12,647,115.

(51) Int. Cl. H03K 19/00; H03K 19/003; H03K 19/017; H03K 19/0948

(52) U.S. Cl. CPC H03K 19/0027; H03K 19/00384; H03K 19/01707; H03K 19/0948

(57) ABSTRACT

Reduced delay and improved threshold tracking over PVT in a comparator input circuit and comparator are provided by circuits that include an inverter stage having a first complementary pair of transistors connected in a push-pull configuration. An input of the inverter stage is coupled to the gates of the first complementary pair of transistors, and an output of the inverter is coupled to the drains of the first complementary pair of transistors. The circuits also include one or more first degeneration transistors coupled between a source of one of the first complementary pair of transistors and a power supply rail of the circuit, and a reference circuit with an output coupled to one or more gates of the first degeneration transistors. The reference circuit controls the one or more first degeneration transistors to cause the inverter stage to have a threshold voltage equal to a threshold control voltage.

### BACKGROUND

### 1. Field of Disclosure

The field of representative embodiments of this disclosure relates to inverter circuits, and in particular to binary inverters having a configurable threshold voltage.

### 2. Background

Binary inverters, e.g., analog amplifiers with high gain in which the output is treated as a binary digital value, are used in many applications, including communications receivers and data converters, e.g., ADCs and DACs, as well as in other signal acquisition and comparison systems. In applications requiring a rapid throughput, the inherent delay of more complex analog comparators typically cannot be tolerated, and relatively simple inverter-based comparison circuits would be desirable for use as comparators. However, for N-type metal oxide semiconductor (NMOS) and P-type metal oxide semiconductor (PMOS) input stages, level-shifters are typically required to shift the voltage level of the output to be compatible with subsequent processing stages, and for complementary metal-oxide semiconductor (CMOS) input stages, the thresholds of the input stages are not well-defined, are dependent on the power supply voltage, and do not track variations in temperature and process well.

In order to overcome the drawbacks of the above-mentioned MOS comparator circuits, i.e., the process, voltage and temperature (PVT) variation, and in particular, to integrate the MOS input circuits in a Schmitt trigger/hysteresis comparator, which have dual trigger points, more complex schemes are employed using multiplexers to select proper thresholds to stabilize the hysteresis magnitude and position in the signal swing voltage range. The multiplexer circuits, however, are in the signal path, which increases the delay of the comparator circuits.

Therefore, it would be advantageous to provide an inverter input circuit and high-speed comparator that do not require complex schemes within the signal path that increase the delay of the comparator, while providing a threshold that does not overly vary with PVT.

### SUMMARY

Reduced delay and improved threshold tracking over PVT in a comparator input circuit and comparator are provided in inverter circuits, comparators incorporating the input circuits, and their methods of operation.

The circuits include an inverter stage including a first complementary pair of transistors connected in a push-pull configuration. An input of the inverter stage is coupled to the gates of the first complementary pair of transistors, and an output of the inverter is coupled to the drains of the first complementary pair of transistors. The circuits also include one or more first degeneration transistors coupled between a source of one of the first complementary pair of transistors and a power supply rail of the circuit, and a reference circuit with an output coupled to one or more gates of the one or more first degeneration transistors. The reference circuit controls the one or more first degeneration transistors to cause the inverter stage to have a threshold voltage equal to a threshold control voltage.

The summary above is provided for brief explanation and does not restrict the scope of the claims. The description below sets forth example embodiments according to this disclosure. Further embodiments and implementations will be apparent to those having ordinary skill in the art. Persons having ordinary skill in the art will recognize that various equivalent techniques may be applied in lieu of, or in conjunction with, the embodiments discussed below, and all such equivalents are encompassed by the present disclosure.

### BRIEF DESCRIPTION OF THE DRAWINGS

FIG. 1A is a block diagram illustrating an example system 10A, in accordance with an embodiment of the disclosure.

FIG. 1B is a block diagram illustrating an example system 10B, in accordance with another embodiment of the disclosure.

FIG. 2A is a simplified schematic diagram illustrating structure of, and FIG. 2B is a signal waveform diagram 25 illustrating operation of, an example comparator circuit 20 that may be used to implement comparator circuit 20A within system 10A of FIG. 1A and comparator 20B of FIG. 1B, in accordance with an embodiment of the disclosure.

FIG. 3A is a schematic diagram of an example inverter 30A that may be used to implement inverters 22A and 22B in comparator 20 of FIG. 2A, in accordance with an embodiment of the disclosure.

FIG. 3B is a schematic diagram of another example inverter 30B that may be used to implement inverters 22A and 22B in comparator 20 of FIG. 2A, in accordance with another embodiment of the disclosure.

FIG. 3C is a schematic diagram of an example inverter 30C that may be used to implement inverters 22A and 22B in comparator 20 of FIG. 2A, in accordance with an embodiment of the disclosure.

FIG. 3D is a schematic diagram of another example inverter 30D that may be used to implement inverters 22A and 22B in comparator 20 of FIG. 2A, in accordance with another embodiment of the disclosure.

FIG. 4 is a schematic diagram of another example inverter 40 that may be used to implement inverters 22A and 22B in comparator 20 of FIG. 2A, in accordance with another embodiment of the disclosure.

FIG. 5A and FIG. 5B are schematic diagrams of other example inverters 50A, 50B that may be used to implement inverters 22A and 22B in comparator 20 of FIG. 2A, in accordance with other embodiments of the disclosure.

FIG. 6 is a schematic diagram of another example inverter 60 that may be used to implement inverters 22A and 22B in comparator 20 of FIG. 2A, in accordance with another embodiment of the disclosure.

FIG. 7 is a schematic diagram of another example inverter 70 that may be used to implement inverters 22A and 22B in comparator 20 of FIG. 2A, in accordance with another embodiment of the disclosure.

FIG. 8 is a schematic diagram of an example non-overlapping set-reset circuit 80 that may be used to implement both of inverters 22A and 22B in comparator 20 of FIG. 2A, in accordance with an embodiment of the disclosure.

### DETAILED DESCRIPTION OF ILLUSTRATIVE EMBODIMENT

The present disclosure encompasses binary inverter/analog inverting amplifier comparison circuits, comparator circuits and integrated circuits that include the inverters, which provide reduced delay and improved threshold tracking over PVT. The circuits include an inverter stage including a first complementary pair of transistors connected in a push-pull configuration. An input of the inverter stage is coupled to the gates of the first complementary pair of transistors, and an output of the inverter is coupled to the drains of the first complementary pair of transistors. The input circuits also include one or more first degeneration transistors coupled between a source of one of the first complementary pair of transistors and a power supply rail of the circuit, and a reference circuit with an output coupled to one or more gates of the one or more first degeneration transistors. The reference circuit controls the one or more first degeneration transistors to cause the inverter stage to have a threshold voltage equal to a threshold control voltage.

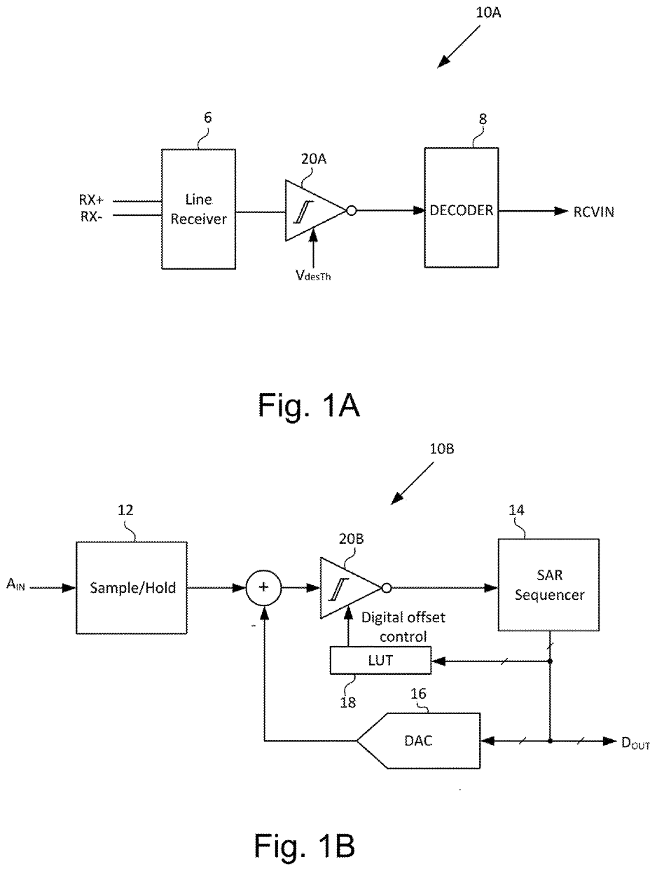

Referring now to FIG. 1A, a block diagram illustrating an example system 10A is shown, in accordance with an embodiment of the disclosure. System 10A implements a receiver portion of a physical-layer (PHY) part of a communications link. A line receiver 6 receives a signal from a differential pair of I/O connection signals RX+, RX−, and a comparator 20A evaluates an output of line receiver 6 according to internal threshold voltages to determine a binary value of the input signal represented by I/O connection signals RX+, RX−. The threshold voltages may be adjusted/configured according to a current state of the output of comparator 20A, so that comparator 20A provides a Schmitt trigger, i.e., comparator 20A may be a Schmitt comparator. The output of comparator 20A is provided to a decoder block 8 that interprets binary sequences of values represented by I/O connection signals RX+, RX− to generate a physical layer output signal RCVIN. The internal threshold voltages of comparator 20A may be controlled/configured by one or more input control signals VdesTh, e.g., two threshold voltages may be provided to adjust an upper and lower threshold used to implement hysteretic response of comparator 20A, or the upper and lower thresholds may have a fixed offset with respect to each other, while input control signal VdesTh adjusts their common-mode voltage. As will be described in more detail below, comparator 20A provides an internal threshold that is stable with process, power supply voltage and temperature (PVT), while introducing minimal delay.

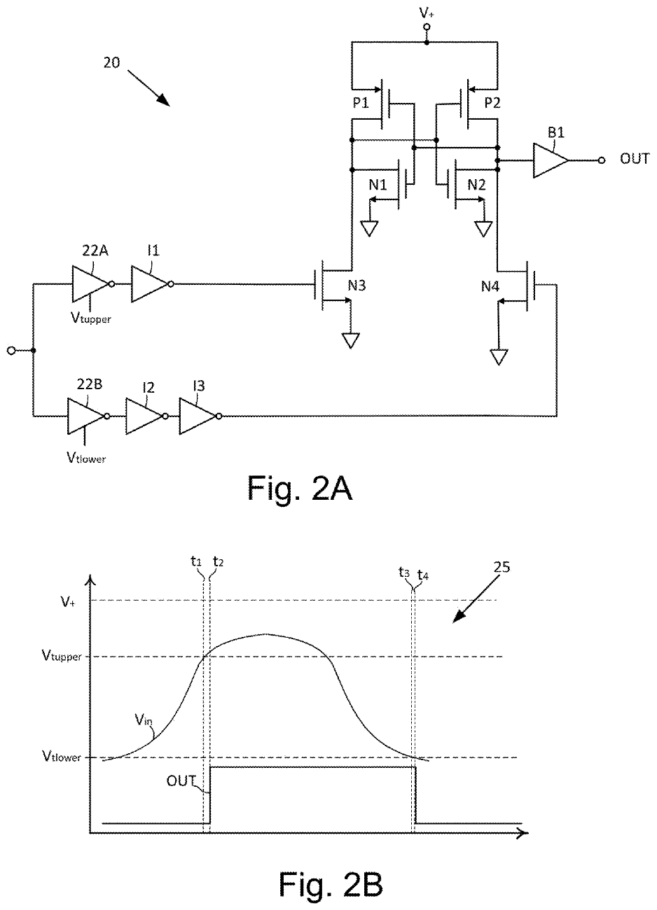

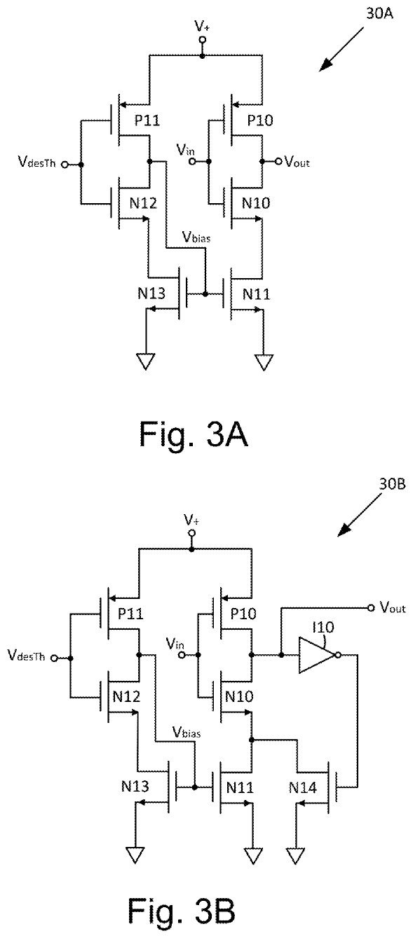

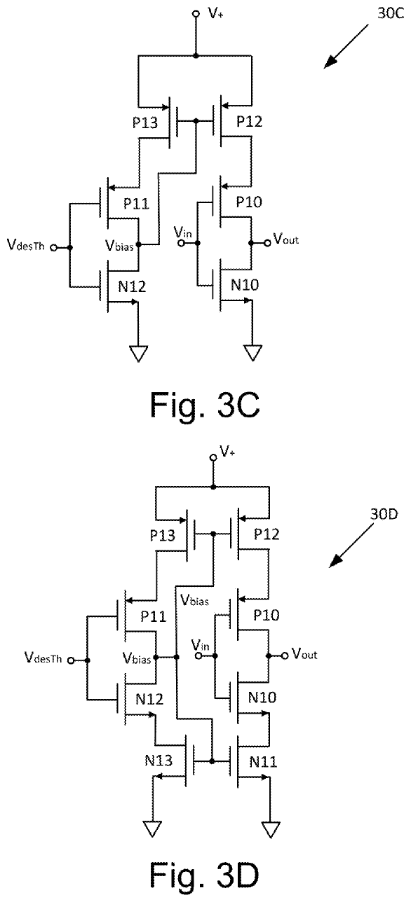

Referring now to FIG. 1B, a block diagram illustrating an example system 10B is shown, in accordance with an embodiment of the disclosure. Example system 10B implements a self-timed successive-approximation register (SAR) analog-to-digital converter (ADC) that converts an analog input signal A_{IN} to a digital value D_{OUT}. Analog input signal A_{IN} is sampled and held by a sample/hold block 12 and, during an evaluation phase, converted to digital output D_{OUT} by a successive approximation process controlled by a SAR sequencer 14 that resolves digital output D_{OUT} one bit at a time from a most-significant bit (MSB) to a least-significant bit (LSB). A digital-to-analog converter (DAC) 16 provides feedback of a present (approximated) value of digital output D_{OUT} provided from SAR sequencer 14, which is subtracted from the output of sample/hold block 12 by a combiner 13. A comparator 20B compares the output of DAC 16 to the difference between the output of sample/hold block 12 and the output of DAC 16, as provided by combiner 13. The evaluation phase terminates once the LSB is resolved, and another conversion cycle may begin. A look-up table (LUT) 18 provides one or more digital control signals based on the current value of the SAR in SAR sequencer 14, which allows for prevention of value-change voltage spikes that typically would occur when DAC 16 changes value by more than an LSB, by changing the offset of comparator 20B to prevent changes of state at the output of comparator 20B that may occur in response to a voltage spike. As will be described in more detail below, comparator 20B provides an internal threshold that is stable with process, power supply voltage and temperature (PVT), while introducing minimal delay, and, in some embodiments, enables varying the threshold voltage via direct digital control. In the illustrated example, comparator 20B is shown as a Schmitt comparator and may be exemplified by comparator circuit 20 of FIG. 2 as described below, but in alternative embodiments, comparator 20B may be a binary inverter/comparator with threshold control, as exemplified by inverters such as inverter 30A of FIG. 3A, and the other exemplary inverters described below.

Referring now to FIG. 2A, a simplified schematic diagram illustrating a comparator circuit 20 that may be used to implement comparator circuit 20A within system 10A of FIG. 1A and comparator 20B of FIG. 1B is shown, in accordance with an embodiment of the disclosure. An input voltage V_{IN} is evaluated by an inverter 22A, according to an internal threshold voltage that is controllable to set an upper threshold voltage by an upper threshold control voltage Vₜᵤₚₚₑᵣ and is provided to a set input of a latch formed by a cross-coupled pair of PMOS transistors P1, P2 and NMOS transistors N1,N2, via a logical inverter I1. When input voltage V_{IN} exceeds upper threshold control voltage Vₜᵤₚₚₑᵣ, the output of inverter 22A assumes a low voltage state, and the output of inverter I1 therefore assumes a high voltage state. Transistor N3 is thereby activated, causing the output Out of comparator circuit 20 to transition to the high-voltage state, since the gates of transistors P2 and N2 are pulled to the low-voltage state, causing transistor P2 to turn on and transistor N2 to turn off, which raises the input of buffer B1 to the high-voltage state. The output of the latch formed by transistors P1, P2 and transistors N1,N2 remains in the high-voltage state, independent of the state of transistor N3, until transistor N4 is activated, which will not occur until inverter 22B transitions to a high-voltage state, i.e., when input voltage V_{IN} falls below a threshold voltage V_{tlower}. When inverter 22B transitions to the high-voltage state, inverters I2 and I3 form a buffer that provides a high-voltage state output signal to the gate of transistor N4, which pulls the gates of transistors N1 and P1 low, and causes the state of the latch formed by transistors P1, P2 and transistors N1,N2 to change, changing output signal OUT to the low-voltage state through buffer B1. Similar to the operation described above, which is illustrated by a signal waveform diagram 25 as shown in FIG. 2B, in which the above-described negative-going output transition is seen at a time t₄ after input voltage V_{IN} falls below lower threshold voltage V_{tlower} at a time t₃, for a positive transition of input voltage V_{IN} crossing upper threshold voltage Vₜᵤₚₚₑᵣ at a time t₁, the output of comparator circuit 20A transitions to a high-voltage state at time a time t₂. Comparator circuit 20A thus provides an inverting Schmitt comparator, since hysteresis is implemented by the presence of a different threshold voltage V_{tlower} for negative transitions of the output signal, than a threshold voltage Vₜᵤₚₚₑᵣ that is applied for positive transitions of the output signal. Various inverter circuits described in further detail below, which themselves may incorporate hysteresis, or not, and which therefore may not require the set-reset latch of comparator 20 to provide hysteresis, may be used as inverters 22A, 22B of comparator circuit 20, in accordance with different embodiments of the disclosure. The inverter circuits may include a reference circuit that is generally of identical design to the inverter circuit or a scaled design, and which incorporates one or more degeneration resistances, which may be provided by transistors. The transistors of the reference circuit may provide a bias voltage that may be adjustable or selectable to change the threshold voltage or may be selectively coupled to the inverter circuit. The use of an identical or scaled design stabilizes the fixed or adjustable/selectable degeneration resistance over process, power supply voltage, and temperature.

Referring now to FIG. 3A, a schematic diagram of an example inverter 30A that may be used to implement inverters 22A and 22B in comparator 20 of FIG. 2A is shown, in accordance with an embodiment of the disclosure. Example inverter 30A inverts input signal Vᵢₙ to an output signal Vₒᵤₜ using a push-pull inverter pair formed by a transistor P10 and a transistor N10. The threshold voltage applied by transistors P10, N10 is adjusted by a degeneration resistance provided by a transistor N11. By varying a bias voltage V_{bias} applied to the gate of transistor N11, the threshold voltage of example inverter 30A is made adjustable. Bias voltage V_{bias} is generated by an example reference circuit that includes another push-pull pair formed by a transistor P11 and a transistor N12. The example reference circuit also includes another degeneration resistance, provided by a transistor N13.which has a gate also controlled by bias voltage V_{bias}, and an input to the push-pull pair formed by a transistor P11 and a transistor N12 is provided by a control voltage VdesTh, which sets the threshold voltage of example inverter 30A to a desired threshold voltage.

Transistors P11, N12 and N13 of the reference circuit may be identical to corresponding transistors P10, N10 and N11, of the push-pull inverter circuit, so that the reference circuit and the inverter circuit track over PVT. Alternatively, transistors P11, N12 and N13 of the reference circuit may be scaled to corresponding transistors P10, N10 and N11 to provide the tracking behavior at a lower current level than that needed for the inverter circuit, to reduce power consumption. The reference circuit thus self-biases to a linear operating point set by control voltage VdesTh, which causes bias voltage V_{bias} to stabilize at a voltage that will cause the push-pull inverter pair formed by a transistor P10 and a transistor N10 to have a threshold voltage equal to control voltage VdesTh. Because the reference circuit drives only a high-impedance node, i.e., the gate of the degeneration transistor(s), the bias voltage V_{bias} is also immunized to load variations over PVT. Example inverter 30A is an example of an inverter circuit in accordance with an embodiment of the disclosure that does not include internal hysteresis, but that may be used in comparator circuit 20 of FIG. 2, to implement a Schmitt trigger/hysteresis comparator.

Referring now to FIG. 3B, a schematic diagram of another example inverter 30B that may be used to implement inverters 22A and 22B in comparator 20 of FIG. 2A is shown, in accordance with another embodiment of the disclosure. Example inverter 30B includes internal hysteresis and is otherwise similar to example inverter 30A of FIG. 3A, so only differences between them are described below. Example inverter circuit 30B includes an inverter I10 that generates a signal complementary to output signal Vₒᵤₜ, and an additional degeneration transistor N14. When input signal Vᵢₙ switches to or starts in a logical-high state, output signal Vₒᵤₜ assumes a logical-low state, and the output of inverter I10 is in a logical-high state, which activates transistor N14. Transistor N14 increases the degeneration provided at the source terminal of transistor N10, which lowers the threshold voltage of the push-pull inverter pair formed by transistor P10 and transistor N10, and consequently lowering the threshold voltage of inverter 30B, providing hysteresis, since input signal Vᵢₙ will have to fall to a lower voltage level to switch the state of the push-pull inverter pair formed by transistor P10 and transistor N10 than would otherwise be required if transistor N14 were absent or not active. The hysteresis may be made symmetric by scaling transistor N11 down to provide a higher degeneration resistance than transistor N13, or single-sided hysteresis may be desirable, e.g., when implementing one of the inverters in comparator 20, where the other one of the inverters is implemented with a PMOS degeneration device to provide high-side hysteresis.

Referring now to FIG. 3C, a schematic diagram of an example inverter 30C that may be used to implement inverters 22A and 22B in comparator 20 of FIG. 2A is shown, in accordance with an embodiment of the disclosure. Example inverter 30C provides an example of an inverter that includes degeneration using a PMOS transistor P12, and a corresponding degeneration transistor P13 in the reference circuit provided in combination with transistors P11 and P12. Example inverter 30C is otherwise similar to example inverter 30B of FIG. 3B, so only differences between them are described above.

Referring now to FIG. 3D, a schematic diagram of another example inverter 30D that may be used to implement inverters 22A and 22B in comparator 20 of FIG. 2A is shown, in accordance with another embodiment of the disclosure. Example inverter 30D provides an example of an inverter that includes degeneration using a CMOS architecture, with degeneration transistors P12, P13 added to example inverter 30A of FIG. 3A, and in which the reference circuit self-biases to cause bias voltage V_{bias} to stabilize at a voltage that will cause the push-pull inverter pair formed by transistors P10, N10 to have a threshold voltage equal to control voltage VdesTh, and in which the degeneration provided to both the reference circuit and the push-pull inverter stage formed by transistors P10, N10 is split between a device (transistor P12) coupled to the positive power supply rail V+ and a device (transistor N11) coupled to the negative/return power supply rail (ground). In general, the degeneration/threshold voltages provided by transistor P12 and transistor N11 would not be symmetrical for a given value of bias voltage V_{bias}, but the size ratios of transistor P12 and transistor N11 may be set for symmetry, or to other values, such as setting one threshold voltage near one of the power supply rails so that the particular transistor is fully-on, and using the transistor coupled to the opposite power supply rail to provide the adjustment of the inverter threshold voltage, which provides the simplest adjustment scheme and a fast output transition time. Example inverter 30D is otherwise similar to example inverter 30A of FIG. 3A and inverter 30C of FIG. 3C, so only differences between them are described above.

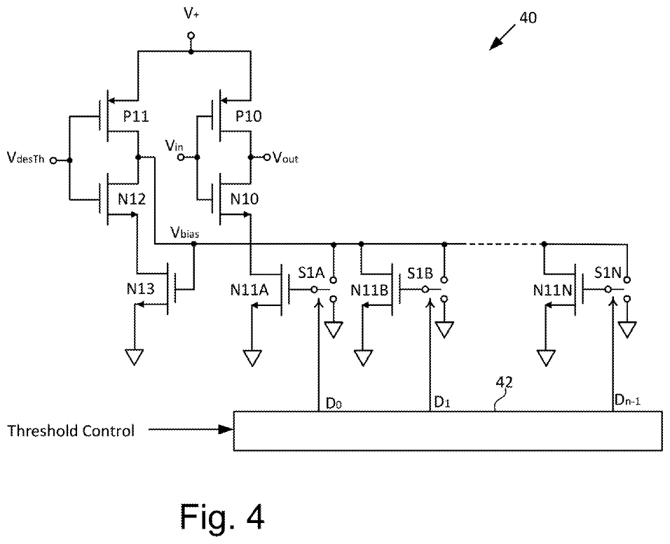

Referring now to FIG. 4, a schematic diagram of another example inverter 40 that may be used to implement inverters 22A and 22B in comparator 20 of FIG. 2A is shown, in accordance with another embodiment of the disclosure. Example inverter 40 is similar to example inverter 30A of FIG. 3A, so only differences between them are described below. Example inverter 40 illustrates a digital version of an inverter 40 in accordance with an embodiment of the disclosure, in which the threshold control signal is a digital signal/signals that are provided to a control circuit 42 that operates a plurality of switches S1A-S1N to select combinations of, or individual ones of a plurality of degeneration transistors N11A-N11N that are coupled to the source terminal of transistor N10. Each of switches S1A-S1N applies either bias voltage V_{bias} or ground, to the gate terminals of degeneration transistors N11A-N11N, according to control outputs D₀-Dₙ₋₁ generated by control circuit 42 according to a control value Threshold Control, so that the reference circuit formed by transistors P11, N12 and N13, tracks PVT variations for the circuit with a nominal selection of degeneration transistors N11A-N11N, but control value Threshold Control permits independent adjustment of the threshold voltage of the inverter formed by transistors P10 and N10.

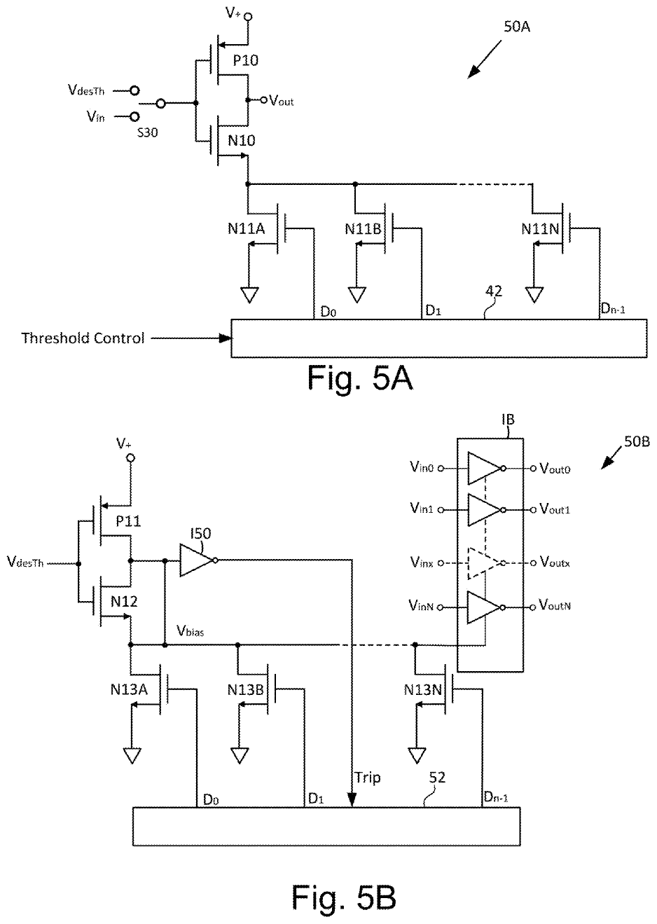

Referring now to FIG. 5A and FIG. 5B, schematic diagrams of other example inverters 50A, 50B that may be used to implement inverters 22A and 22B in comparator 20 of FIG. 2 are shown, in accordance with other embodiments of the disclosure. Example inverters 50A, 50B are similar to example inverter 40 of FIG. 4, so only differences between them are described below. Example inverter 50A is another digital version of an inverter, in which the gate terminals of degeneration transistors N11A-N11N are controlled directly by outputs D₀-Dₙ₋₁ generated by control circuit 42, so that transistors N11A-N11N are either turned fully-on by application of a logical high-level signal or fully-off by a logical low-level signal to adjust the offset of the inverter stage formed by transistors P10, N10. FIG. 5B illustrates another example digital inverter circuit 50B in which a plurality of reference degeneration transistors N13A-N13N are either turned fully-on by application of logical high-level signals or fully-off by logical low-level signal values of outputs D₀-Dₙ₋₁ generated by a control circuit 52 to adjust the offset of the reference circuit push-pull stage formed by transistors P11, N12, thereby adjusting bias voltage V_{bias}. Bias voltage V_{bias} may then be supplied to a plurality of inverter circuits in an inverter bank IB that generates outputs Vₒᵤₜ₀-V_{outN} from corresponding inputs Vᵢₙ₀-V_{inN}, which may form part of, for example, a receiver having multiple parallel channels/bits. Alternatively, to improve threshold tracking over PVT of the individual inverters, outputs D₀-Dₙ₋₁ may be coupled to individual reference circuits associated with each inverter in inverter bank IB. The inverters of inverter bank IB are identical/scaled replicas of the reference circuit with a nominal selection of reference degeneration transistors N13A-N13N, as described above with reference to other examples, which illustrates the ability to duplicate the inverter portion of the circuit for as many inverters as are required for a particular application. Example inverter circuit 50B also illustrates a circuit and method of calibration of the inverter threshold voltage, by adjusting control values D₀-Dₙ₋₁ until a change occurs in the state of an input signal Trip provided to an input of control circuit 52 by an inverter I50 that evaluates bias voltage V_{bias}, indicating that bias voltage V_{bias} has reached a voltage corresponding to desired threshold control voltage VdesTh. For example, control circuit 52 may be a counter that increments a number corresponding to control values D₀-Dₙ₋₁ and reference degeneration transistors N13A-N13N may have on-resistances that are binary-weighted, so that a change in control values D₀-Dₙ₋₁ represents a change in degeneration resistance and thus a corresponding change in threshold voltage. Alternatively, the weighting of reference degeneration transistors N13A-N13N may be equal, or according to a weighting other than binary, in order to provide a desired range of offset control.

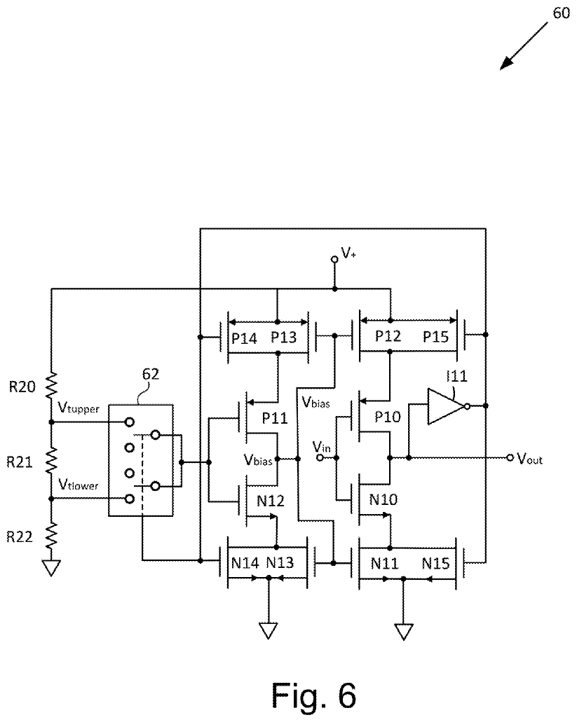

Referring now to FIG. 6, a schematic diagram of another example inverter 60 that may be used to implement inverters 22A and 22B in comparator 20 of FIG. 2A is shown, in accordance with another embodiment of the disclosure. Example inverter 60 is similar to example inverter 30D of FIG. 3D, so only differences between them are described below. As in inverter 30D, inverter 60 employs a CMOS topology, with additional degeneration transistors P15 and N15 included to apply hysteresis to the push-pull inverter circuit formed by transistors N10, P10, N11, and P12 as controlled by output signal Vₒᵤₜ and an inverted version of output signal Vₒᵤₜ provided by an inverter I11. Additionally, a switching circuit 62 controls the threshold voltage applied to the input of the reference circuit formed by transistors P11, N12, P13 and N13 and additional degeneration transistors P14, N14 that are switched according to the state of the inverted version of output signal Vₒᵤₜ provided by inverter I11, which maintains the same degeneration resistance presence in the reference circuit as in the push-pull inverter circuit. A voltage divider formed by resistors R20-R22 generates two threshold control voltage levels Vᵤₚₚₑᵣ and V_{lower}, which are selected by switching circuit 62 according to the state of output signal Vₒᵤₜ, which applies a hysteresis offset at the input of the reference circuit, i.e., to the gates of transistors P11, N12. Resistor R20 and R22 will generally be of equal value, so that the hysteresis is symmetrical about the midpoint of power supply voltage V₊.

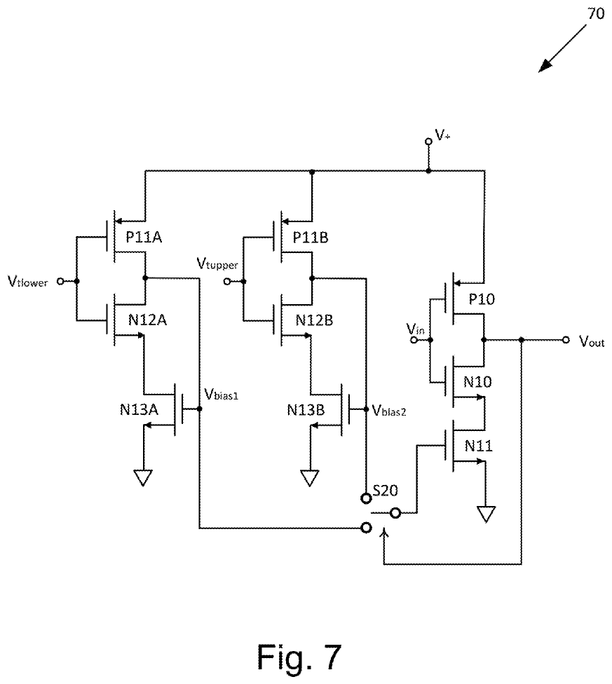

Referring now to FIG. 7, a schematic diagram of another example inverter 70 that may be used to implement inverters 22A and 22B in comparator 20 of FIG. 2A is shown, in accordance with another embodiment of the disclosure. Example inverter 70 provides hysteresis, but is otherwise similar to example inverter 30A of FIG. 3A, so only differences between them are described below. Rather than adding or removing transistors to change the degeneration resistance in parallel with transistor N11, or in parallel with transistor N13A to change the reference degeneration resistance, in example inverter 70 two separate reference circuits, one implemented by transistors P11A, N12A and N13A, and another implemented by transistors P11B, N12B and N13B, generate two bias voltages: V_{bias1} and V_{bias2}, respectively. A switch S20 selects between applying bias voltage V_{bias1} or bias voltage V_{bias2} to the gate of transistor N11, according to the state of output signal Vₒᵤₜ, setting hysteresis thresholds directly according to control voltages V_{tlower} and Vₜᵤₚₚₑᵣ, which are provided as inputs to the two corresponding reference circuits.

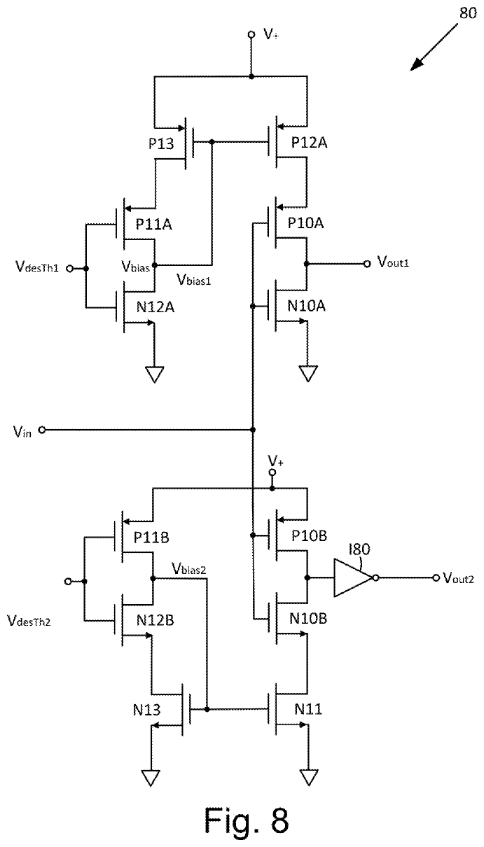

Referring now to FIG. 8, a schematic diagram of an example non-overlapping set-reset circuit 80 that may be used to implement both of inverters 22A and 22B in comparator 20 of FIG. 2A is shown, in accordance with an embodiment of the disclosure. A first inverter circuit, which may be identical in construction to PMOS-topology inverter circuit 30C of FIG. 3C, is formed by transistors P10A, N10A, P11A, N12A, P12A and P13, receives a first control threshold voltage V_{desTh1} at an input of the reference circuit, i.e., the gates of transistors P11A, N12A, and has an internal bias voltage V_{bias1}. A second inverter circuit of NMOS topology, which may be identical in construction to inverter circuit 30A of FIG. 3A, is formed by transistors P10B, N10B, N11, P11B, N12B, and N13, receives a second threshold control voltage V_{desTh2} at an input of the reference circuit, i.e., the gates of transistors P11B, N12B, and has an internal bias voltage V_{bias2}. The output of the second inverter provided at the drain terminals of transistors P10B, N10B is inverted by an inverter I80. The resulting operation of set-reset circuit 80, generates a set output V_{OUT1} when input signal Vᵢₙ exceeds first threshold control voltage V_{desTh1} and a reset signal at output V_{OUT2} falls below second threshold control voltage V_{desTh2}. The resulting circuit may be used directly to implement inverters 22A and 22B of FIG. 2A, as mentioned above, and which provide respective set and reset inputs to the gates of transistors N3 and N4 in comparator 20 of FIG. 2 to set and reset the cross-coupled latch.

In summary, this disclosure shows and describes circuits and integrated circuits implementing an inverter stage that may be used in a Schmitt trigger/hysteresis comparator or an analog-to-digital converter. The circuit may include an inverter stage having a first complementary pair of transistors connected in a push-pull configuration, and an input of the inverter stage may be coupled to the gates of the first complementary pair of transistors. An output of the inverter may be coupled to the drains of the first complementary pair of transistors, and the circuit may also include one or more first degeneration transistors coupled between a source of one of the first complementary pair of transistors and a power supply rail of the circuit. The circuit may also include a reference circuit having an output coupled to one or more gates of the one or more first degeneration transistors, and that may control the one or more first degeneration transistors to cause the inverter stage to have a threshold voltage equal to a threshold control voltage.

In some example embodiments, the reference circuit may include a second complementary pair of transistors connected in a push-pull configuration, and an input of the reference circuit may be coupled to the gates of the second complementary pair of transistors and receives the threshold control voltage. The output of the reference circuit may be provided from a connection coupled to the drains of the second complementary pair of transistors, and the circuit may also include a reference degeneration transistor coupled between a source of one of the second complementary pair of transistors and the power supply rail of the circuit. A gate of the reference degeneration transistor and a gate of the first degeneration transistor may be coupled to the output of the reference circuit and receive a bias voltage therefrom, so that the threshold control voltage adjusts the threshold of the inverter.

In some example embodiments, the output of the reference circuit may be selectably coupled to the one or more gates of the one or more first degeneration transistors, so that the adjustment of the threshold of the inverter is disabled when coupling of the output of the reference circuit to the gate of the first degeneration transistor is deselected. In some example embodiments, the reference degeneration transistor may be coupled between a negative power supply rail and a source of an N-channel device of the first complementary pair of transistors, and the circuit may also include one or more second degeneration transistors coupled between a source of a P-channel device of the first complementary pair of transistors and a positive power supply rail of the circuit. The gate of the reference degeneration transistor may be coupled to the gate of the third degeneration transistor.

In some example embodiments, the reference degeneration transistor may be coupled between a negative power supply rail and a source of an N-channel device of the first complementary pair of transistors, the reference circuit may be a first reference circuit, the bias voltage may be first bias voltage, and the threshold control voltage may be a first threshold control voltage. The circuit may further include a third degeneration transistor coupled between a source of a P-channel device of the first complementary pair of transistors and a positive power supply rail of the circuit, and a second reference circuit for providing a second bias voltage to a gate of the third degeneration transistor. The second reference circuit may include a third complementary pair of transistors connected in a push-pull configuration, and an input of the second reference circuit may be coupled to the gates of the third complementary pair of transistors and receive a second threshold control voltage. An output of the second reference circuit may be provided from a connection coupled to the drains of the third complementary pair of transistors.

In some example embodiments, the inverter stage may be a first inverter stage, the input of the first inverter stage may be an input to Schmitt comparator, and the reference degeneration transistor may be coupled between a negative power supply rail and a source of an N-channel device of the first complementary pair of transistors. The reference circuit may be a first reference circuit, the bias voltage may be a first bias voltage, and the threshold control voltage may be a lower switching threshold. The circuit may further include a second inverter stage including a third complementary pair of transistors connected in a push-pull configuration, and an input of the second inverter stage may be coupled to the gates of the third complementary pair of transistors and to the input of the first inverter stage. An output of the second inverter stage may be coupled to the drains of the third complementary pair of transistors, and the circuit may include a third degeneration transistor coupled between a source of one of the third complementary pair of transistors and a positive power supply rail of the circuit, a second reference circuit for providing a second bias voltage to a gate of the third degeneration transistor. The second reference circuit may include a fourth complementary pair of transistors connected in a push-pull configuration. An input of the second reference circuit may be coupled to the gates of the fourth complementary pair of transistors and receive an upper threshold control voltage, and an output of the second reference circuit may be provided from a connection coupled to the drains of the fourth complementary pair of transistors. The circuit may also include a cross-coupled latch having a set input coupled to an output of the first inverter stage and a reset input coupled to an output of the second inverter stage, so that the output of the cross-coupled latch provides an output of the Schmitt comparator.

In some example embodiments, the circuit may further include a bypass circuit coupled between a source and a drain of the one or more degeneration transistors that may be enabled according to a state of the output of the first inverter stage to bypass the one or more degeneration transistors, so that the bypass circuit adds hysteresis to a switching characteristic of the inverter. In some example embodiments, the inverter may be decision stage of one-bit ADC. In some example embodiments, the reference circuit may further include switching circuit that selects one of a plurality of bias voltages to supply the threshold control voltage to the reference circuit. In some example embodiments, the switching circuit may have a control input coupled to an output of the inverter.

In some example embodiments, the one or more first degeneration transistors may include multiple degeneration transistors, and the circuit may further include a switching circuit that selectively couples the one or more first degeneration transistors between the source of one of the second complementary pair of transistors and the power supply rail of the circuit according to a digital control value. In some example embodiments. the one or more first degeneration transistors may include multiple degeneration transistor, and the circuit may also include a switching circuit that selectively couples gates of the one or more first degeneration transistors to the bias voltage or the power supply rail of the circuit according to a digital control value.

In some example embodiments, the reference circuit may further include a switching circuit coupled to gates of the one or more first degeneration transistors to individually activate the one or more first degeneration transistors according to a digital control value, and the switching circuit may be coupled to the input of the inverter stage to selectively apply the threshold control voltage to the input of the inverter stage. The circuit may also include a control circuit that operates the switching circuit successively by adjusting the digital control value to activate the one or more first degeneration transistors while the threshold control voltage is applied to the input of the inverter until the output of the inverter stage changes state at a terminal value of the digital control value. The control circuit may maintain the digital control value at the terminal value during subsequent operation of the inverter.

While the disclosure has shown and described particular embodiments of the techniques disclosed herein, it will be understood by those skilled in the art that the foregoing and other changes in form, and details may be made therein without departing from the spirit and scope of the disclosure. For example, the techniques shown above may be applied to other types of circuits that include inverter or comparator topologies.

What is claimed is:

1. A circuit, comprising:
an inverter stage including a first complementary pair of transistors connected in a push-pull configuration, wherein an input of the inverter stage is coupled to gates of the first complementary pair of transistors and an output of the inverter is coupled to drains of the first complementary pair of transistors;
an input terminal that receives a threshold control voltage that sets a desired threshold voltage of the inverter;
one or more first degeneration transistors coupled between a source of one of the first complementary pair of transistors and a power supply rail of the circuit; and
a reference circuit having an input coupled to the input terminal and having an output coupled to one or more gates of the one or more first degeneration transistors and that controls the one or more first degeneration transistors to cause the inverter stage to have a threshold voltage equal to the desired threshold voltage.

2. The circuit of claim 1, wherein the reference circuit comprises a second complementary pair of transistors connected in a push-pull configuration, wherein an input of the reference circuit is coupled to the gates of the second complementary pair of transistors and receives the threshold control voltage, and wherein the output of the reference circuit is provided from a connection coupled to the drains of the second complementary pair of transistors, wherein the circuit further comprises a reference degeneration transistor coupled between a source of one of the second complementary pair of transistors and the power supply rail of the circuit, and wherein a gate of the reference degeneration transistor and a gate of the first degeneration transistor are coupled to the output of the reference circuit and receive a bias voltage therefrom, whereby the threshold control voltage adjusts the threshold voltage of the inverter.

3. The circuit of claim 2, wherein the reference degeneration transistor is coupled between a negative power supply rail and a source of an N-channel device of the first complementary pair of transistors, wherein the reference circuit is a first reference circuit, wherein the bias voltage is a first bias voltage, wherein the threshold control voltage is a first threshold control voltage, and wherein the circuit further comprises:
a second degeneration transistor coupled between a source of a P-channel device of the first complementary pair of transistors and a positive power supply rail of the circuit; and
a second reference circuit for providing a second bias voltage to a gate of the second degeneration transistor, wherein the second reference circuit comprises a third complementary pair of transistors connected in a push-pull configuration, wherein an input of the second reference circuit is coupled to the gates of the third complementary pair of transistors and receives a second threshold control voltage from a second input terminal, and wherein an output of the second reference circuit is provided from a connection coupled to the drains of the third complementary pair of transistors.

4. The circuit of claim 1, further comprising a bypass circuit coupled between a source and a drain of the one or more first degeneration transistors and that is enabled according to a state of the output of the first inverter stage to bypass the one or more first degeneration transistors, whereby the bypass circuit adds hysteresis to a switching characteristic of the inverter.

5. The circuit of claim 1, wherein the inverter is a decision stage of a one-bit analog-to-digital converter.

6. The circuit of claim 1, wherein the reference circuit further comprises a switching circuit that selects one of a plurality of bias voltages to supply the threshold control voltage to the reference circuit.

7. The circuit of claim 6, wherein the switching circuit has a control input coupled to the output of the inverter.

8. The circuit of claim 1, wherein the one or more first degeneration transistors comprises multiple degeneration transistors, and wherein the circuit further comprises a switching circuit that selectively couples the one or more first degeneration transistors between the drain of one of the second complementary pair of transistors and the power supply rail of the circuit according to a digital control value.

9. The circuit of claim 1, wherein the one or more first degeneration transistors comprises multiple degeneration transistors, and wherein the circuit further comprises a switching circuit that selectively couples the one or more gates of the one or more first degeneration transistors to the bias voltage or the power supply rail of the circuit according to a digital control value.

10. The circuit of claim 1, wherein the reference circuit further comprises:
a switching circuit coupled to gates of the one or more first degeneration transistors to individually activate the one or more first degeneration transistors according to a digital control value, and wherein the switching circuit is coupled to the input of the inverter stage to selectively apply the threshold control voltage to the input of the inverter stage; and
a control circuit that operates the switching circuit to successively adjust the digital control value to activate the one or more first degeneration transistors while the threshold control voltage is applied to the input of the inverter until the output of the inverter stage changes state at a terminal value of the digital control value, and wherein the control circuit maintains the digital control value at the terminal value during subsequent operation of the inverter and de-selects application of the threshold control voltage from the input of the inverter stage.

11. The circuit of claim 10, wherein the inverter stage is a first inverter stage, wherein the switching circuit is a first switching circuit, wherein the input of the first inverter stage is an input to Schmitt comparator, wherein the reference degeneration transistor is coupled between a negative power supply rail and a source of an N-channel device of the first complementary pair of transistors, wherein the reference circuit is a first reference circuit, wherein the threshold control voltage is a lower threshold control voltage, and wherein the circuit further comprises:
a second inverter stage including a third complementary pair of transistors connected in a push-pull configuration, wherein an input of the second inverter stage is coupled to the gates of the third complementary pair of transistors and to the input of the first inverter stage, and wherein an output of the second inverter stage is coupled to the drains of the third complementary pair of transistors;
a second plurality of degeneration transistors coupled between a source of one of the third complementary pair of transistors and a positive power supply rail of the circuit;
a second reference circuit comprising a second switching circuit coupled to gates of the second plurality of degeneration transistors to individually activate the second degeneration transistors according to a second digital control value, and wherein the second switching circuit is coupled to the input of the inverter stage to selectively apply the upper threshold control voltage to the input of the inverter stage, wherein the control circuit further successively activates the gates of second plurality of degeneration transistors while the threshold control voltage is applied to the input of the inverter until the output of the inverter stage changes state at a second terminal one of the second digital control value, and wherein the control circuit maintains the second digital control value at the second terminal value during subsequent operation of the inverter; and
a cross-coupled latch having a set input coupled to an output of the first inverter stage and a reset input coupled to an output of the second inverter stage, whereby the output of the cross-coupled latch provides an output of the Schmitt comparator.

12. A method of inverting an input signal, comprising:
receiving an input signal at an input of an inverter stage, the inverter stage including a first complementary pair of transistors connected in a push-pull configuration, wherein the input of the inverter stage is coupled to gates of the first complementary pair of transistors and an output of the inverter is coupled to drains of the first complementary pair of transistors;
controlling a threshold voltage of the inverter stage with one or more first degeneration transistors coupled between a source of one of the first complementary pair of transistors and a power supply rail and a reference circuit having an output coupled to one or more gates of the one or more first degeneration transistors, wherein the reference circuit controls the one or more first degeneration transistors to cause the inverter stage to have a threshold voltage equal to a threshold control voltage.

13. The method of claim 12, further comprising:
receiving the threshold control voltage as a first threshold control voltage at an input of the reference circuit, wherein the reference circuit is a first reference circuit comprising a second complementary pair of transistors connected in a push-pull configuration, and wherein the threshold control voltage is provided to the gates of the second complementary pair of transistors;
providing the output of the first reference circuit from a connection coupled to the drains of the second complementary pair of transistors;
biasing the first reference circuit with a first bias voltage applied to a gate of a reference degeneration transistor coupled between a source of an N-channel device of the second complementary pair of transistors and a negative power supply rail;
biasing the inverter with the bias voltage by applying the bias voltage to the one or more corresponding gates of the one or more first degeneration transistors;
further controlling the threshold voltage of the inverter by coupling a second degeneration transistor between a source of a P-channel device of the first complementary pair of transistors and a positive power supply rail; and
biasing the second degeneration transistor with a second reference circuit that provides a second bias voltage to a gate of the second degeneration transistor, wherein the second reference circuit comprises a third complementary pair of transistors connected in a push-pull configuration, wherein an input of the second reference circuit is coupled to the gates of the third complementary pair of transistors and receives a second threshold control voltage, and wherein an output of the second reference circuit is provided from a connection coupled to the drains of the third complementary pair of transistors.

14. The method of claim 13, wherein the inverter stage is a first inverter stage, wherein the input of the first inverter stage is an input to Schmitt comparator, wherein the reference degeneration transistor is coupled between a negative power supply rail and a source of an N-channel device of the first complementary pair of transistors, wherein the reference circuit is a first reference circuit, wherein the bias voltage is a first bias voltage, wherein the threshold control voltage is a lower threshold control voltage, and wherein the method further comprises:
receiving the input signal at an input of a second inverter stage, the second inverter stage including a third complementary pair of transistors connected in a push-pull configuration, wherein the input of the second inverter stage is coupled to gates of the third complementary pair of transistors and an output of the second inverter is coupled to drains of the third complementary pair of transistors;
controlling a threshold voltage of the second inverter stage with one or more third degeneration transistors coupled between a source of one of the third complementary pair of transistors and a positive power supply rail and a second reference circuit having an output coupled to one or more gates of the one or more third degeneration transistors, wherein the second reference circuit controls the one or more third degeneration transistors to cause the second inverter stage to have a threshold voltage equal to an upper threshold control voltage; and
capturing state changes of the first inverter stage and the second inverter stage with a cross-coupled latch having a set input coupled to the output of the first inverter stage and a reset input coupled to the output of the second inverter stage, whereby the output of the cross-coupled latch provides an output of a Schmitt comparator.

15. The method of claim 12, further comprising bypassing the one or more first degeneration transistors with a bypass circuit coupled between a source and a drain of the one or more first degeneration transistors, according to a state of the output of the inverter stage to bypass the one or more first degeneration transistors, whereby the bypass circuit adds hysteresis to a switching characteristic of the inverter.

16. The method of claim 12, wherein the inverter is a decision stage of a one-bit ADC.

17. The method of claim 12, further comprising selecting one of a plurality of bias voltages with a switching circuit threshold control voltage to the reference circuit.

18. The method of claim 17, further comprising receiving a control input to the switching circuit from the output of the inverter stage.

19. The method of claim 12, wherein the one or more first degeneration transistors comprises multiple degeneration transistors, and wherein the method further comprises selectively coupling the one or more first degeneration transistors between the drain of one of the second complementary pair of transistors and the power supply rail according to a digital control value.

20. The method of claim 12, wherein the one or more first degeneration transistors comprises multiple degeneration transistors, and wherein the method further comprises selectively coupling the one or more gates of the one or more first degeneration transistors to the bias voltage or the power supply rail according to a digital control value.

21. The method of claim 12, further comprising:
individually activating the one or more first degeneration transistors according to a digital control value supplied to a switching circuit coupled to the input of the inverter stage that selectively applies the threshold control voltage to the input of the inverter stage; and
controlling the switching circuit to successively adjust the digital control value to activate the one or more first degeneration transistors while the threshold control voltage is applied to the input of the inverter; and
responsive to the output of the inverter stage changing state at a terminal value of the digital control value, maintaining the digital control value at the terminal value during subsequent operation of the inverter, and deselecting application of the threshold control voltage from the input of the inverter stage.

22. The method of claim 21, wherein the inverter stage is a first inverter stage, wherein the switching circuit is a first switching circuit, wherein the input of the first inverter stage is an input to Schmitt comparator, wherein the reference degeneration transistor is coupled between a negative power supply rail and a source of an N-channel device of the first complementary pair of transistors, wherein the reference circuit is a first reference circuit, wherein the threshold control voltage is a lower switching threshold, and wherein the method further comprises:
receiving the input signal at an input of a second inverter stage, the second inverter stage including a third complementary pair of transistors connected in a push-pull configuration, wherein the input of the second inverter stage is coupled to the gates of the third complementary pair of transistors and an output of the inverter is coupled to the drains of the third complementary pair of transistors;
controlling a threshold voltage of the second inverter stage with one or more third degeneration transistors coupled between a source of one of the third complementary pair of transistors and a power supply rail and a second reference circuit having an output coupled to one or more gates of the one or more third degeneration transistors, wherein the second reference circuit controls the one or more third degeneration transistors to cause the second inverter stage to have a threshold voltage equal to an upper threshold control voltage; and
capturing state changes of the first inverter stage and the second inverter stage with a cross-coupled latch having a set input coupled to an output of the first inverter stage and a reset input coupled to an output of the second inverter stage, whereby the output of the cross-coupled latch provides an output of a Schmitt comparator.
